(19) United States
(12) Patent Application Publication
(10) Pub. No.: US 2024/0387341 A1
(43) Pub. Date: Nov. 21, 2024

(54) EMBEDDING BARRIER LAYER IN FINE-PITCH BOND STRUCTURES

(71) Applicant: Taiwan Semiconductor Manufacturing Co., Ltd., Hsinchu (TW)

(72) Inventors: Shin-Puu Jeng, Hsinchu (TW); Meng-Liang Lin, Hsinchu (TW); Chieh-Lung Lai, Taichung City (TW); Hsien-Wei Chen, Hsinchu (TW)

(21) Appl. No.: 18/465,622

(22) Filed: Sep. 12, 2023

Related U.S. Application Data
(60) Provisional application No. 63/502,689, filed on May 17, 2023.

(51) Int. Cl. H01L 23/498; H01L 21/48; H01L 23/00

(52) U.S. Cl. CPC H01L 23/49827; H01L 21/4825; H01L 21/486; H01L 24/03; H01L 24/05; H01L 2224/05009; H01L 2224/05025

(57) ABSTRACT

A method forming a redistribution line, which includes a via and a metal trace over and joined to the via, over a carrier. The formation of the redistribution line includes depositing a first metal layer, depositing a barrier layer over the first metal layer, and depositing a second metal layer over the barrier layer. The method further includes de-bonding the redistribution line from the carrier, and bonding a package component to the redistribution line, wherein a metal bump bonds the package component to the via.

### PRIORITY CLAIM AND CROSS-REFERENCE

This application claims the benefit of the following provisionally filed U.S. Patent application: Application No. 63/502,689, filed on May 17, 2023, and entitled “Package Structure and method for Forming the Same,” which application is hereby incorporated herein by reference.

### BACKGROUND

In the packaging of integrated circuits, a plurality of device dies may be bonded to a redistribution structure. For example, device dies and Independent Passive Devices (IPDs) may be bonded to a redistribution structure. Increasingly smaller bond structures are used, and new problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-10 illustrate the cross-sectional views of intermediate stages in the formation of a package in accordance with some embodiments.

FIGS. 11-16 illustrate the cross-sectional views in the formation of embedded vias in accordance with some embodiments.

FIGS. 17-20 illustrate some details in some processes in accordance with some embodiments.

FIGS. 21-25 illustrate the cross-sectional of some embedded vias in accordance with some embodiments.

FIG. 26 illustrates a top view of a redistribution line and the corresponding via in accordance with some embodiments.

FIG. 27 illustrates a process flow for forming a package including the embedded vias in accordance with some embodiments.

FIG. 28 illustrates a process flow for forming bond structures including embedded vias in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package and the method of forming the same are provided. In accordance with some embodiments of the present disclosure, a bond structure including an embedded via is formed, and a via (also referred to as a via pad) is formed based on the embedded via. The embedded via includes a first copper layer and a barrier layer on the first copper layer. A second copper layer may be formed on the barrier layer. By embedding the barrier layer in the embedded via, the formation of Inter-Metallic Compound (IMC) between the via pad and a solder region is limited, and the voids and the resulting interconnect failure is avoided. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

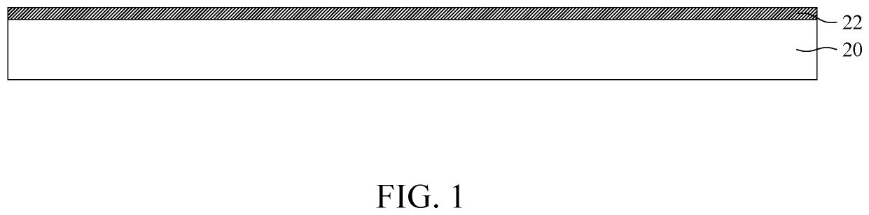

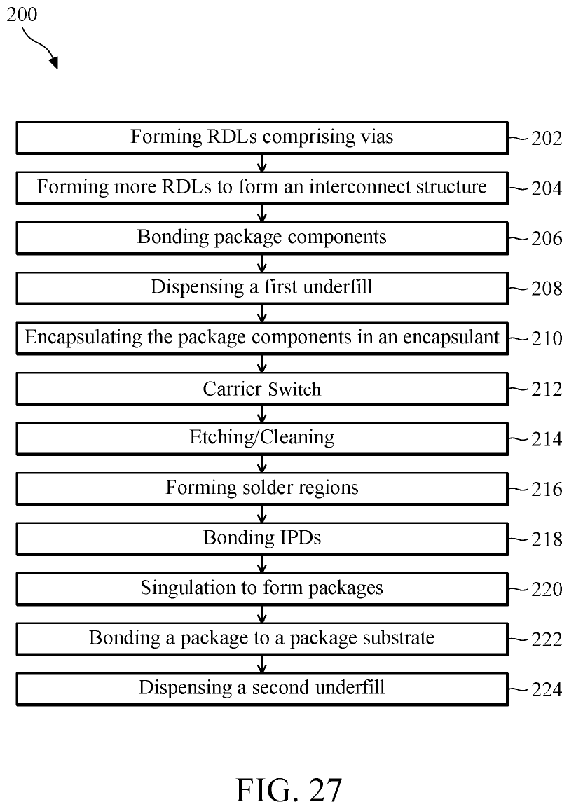

FIGS. 1 through 10 illustrate the cross-sectional views of intermediate stages in the formation of a package in accordance with some embodiments of the present disclosure. The corresponding processes are also reflected schematically in the process flow shown in FIG. 27.

FIG. 1 illustrates carrier 20, and release film 22 on carrier 20. Carrier 20 may be a glass carrier, a silicon wafer, an organic carrier, or the like. Carrier 20 may have a round top-view shape in accordance with some embodiments. Release film 22 may be formed of a polymer-based material and/or an epoxy-based thermal-release material (such as a Light-To-Heat-Conversion (LTHC) material), which is capable of being decomposed under radiation such as a laser beam, so that carrier 20 may be de-bonded from the overlying structures that will be formed in subsequent processes. In accordance with some embodiments of the present disclosure, release film 22 is applied on carrier 20 through coating.

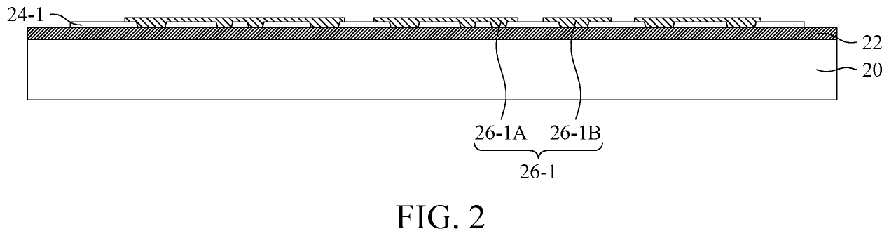

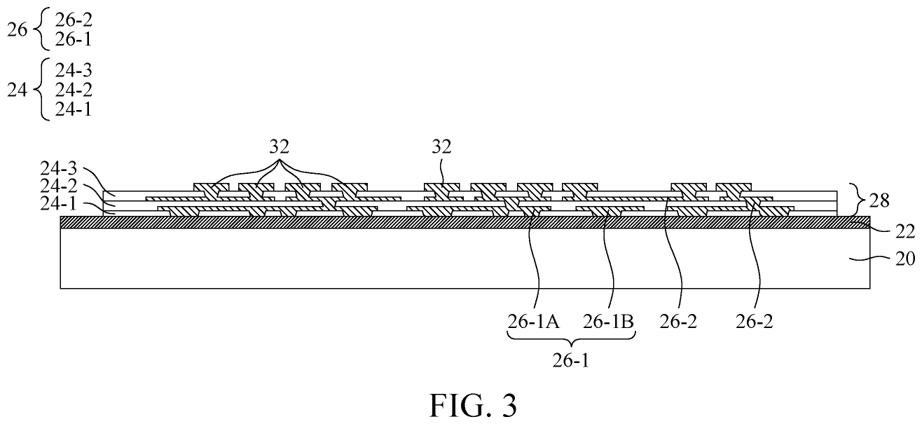

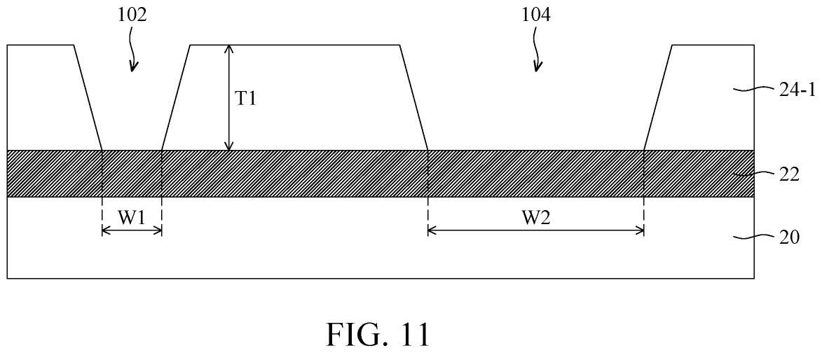

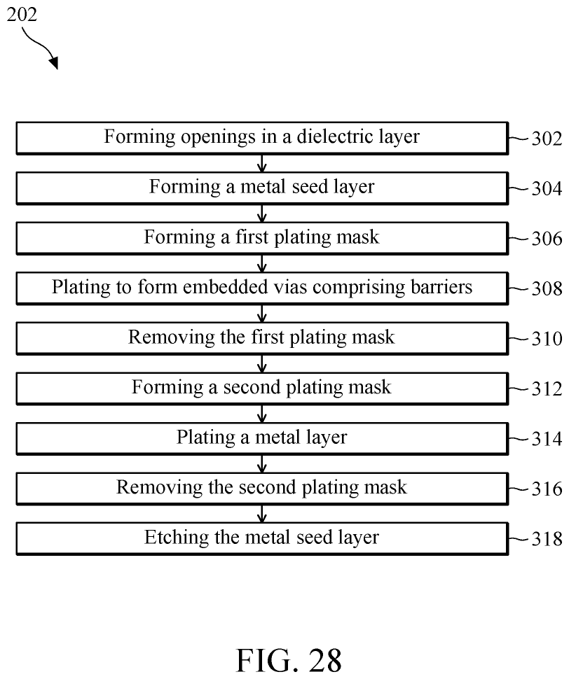

FIGS. 2 and 3 illustrate the formation of a redistribution structure 28, which includes a plurality of dielectric layers 24 and a plurality of RDLs 26. Redistribution structure 28 is alternatively referred to as interposer 28. Redistribution structure 28 may be an organic interposer comprising organic dielectric layers and redistribution lines. In accordance with some embodiments, redistribution structure 28 is formed layer-by-layer starting from release film 22. Referring to FIG. 2, in the formation of redistribution structure 28, a first dielectric layer 24-1 is formed on release film 22, and is then patterned to form openings. A first plurality of Redistribution Lines (RDLs) 26 (denoted as 26-1) are formed on dielectric layer 24-1. The respective process is illustrated as process 202 in the process flow 200 as shown in FIG. 27. The details for forming RDLs 26-1 is illustrated in FIGS. 11 through 16, as discussed below. The detailed processes are also illustrated as process flow 202 as shown in FIG. 28.

FIGS. 11 through 16 illustrate the process flows for the formation of RDLs 26-1, which include embedded vias therein, in accordance with some embodiments. Referring to FIG. 11, dielectric layer 24-1 is formed. In accordance with some embodiments of the present disclosure, dielectric layer 24-1 is formed of or comprises an organic material, which may be a polymer. The organic material may also be a photo-sensitive material. For example, dielectric layer 24-1 may be formed of or comprise polyimide, polybenzoxazole (PBO), benzocyclobutene (BCB), or the like. The thickness T1 of dielectric layer 24-1 may be in the range between about 0.5 μm and about 5 μm.

Openings 102 and 104 are formed in dielectric layer 24-1. The respective process is illustrated as process 302 in the process flow 202 as shown in FIG. 28. In accordance with some embodiments in which dielectric layer 24-1 is a photo-sensitive layer, openings 102 and 104 may be formed by exposing dielectric layer 24-1 through a light-exposure process, followed by a development process. In accordance with alternative embodiments, openings 102 and 104 may be formed through etching. The width W1 of opening 102 may be in the range between about 5 μm and about 50 μm. The width W2 of opening 104 is greater than width W1, for example, with ratio W1/W2 being in the range between about 0.1 and about 0.95.

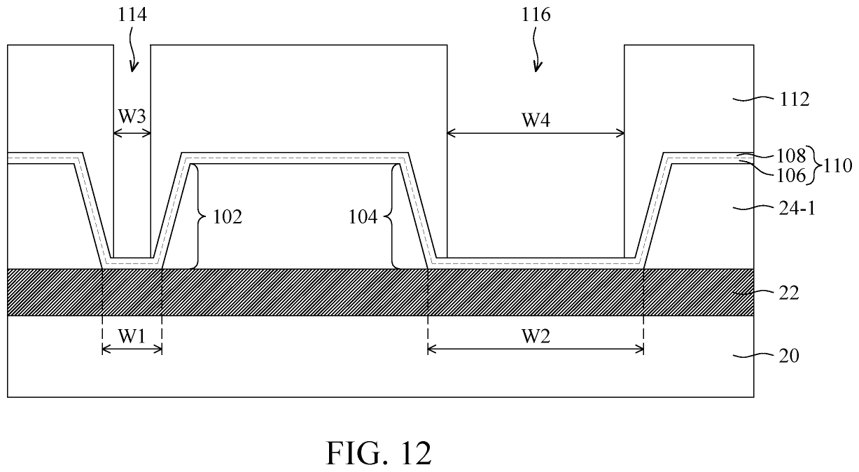

Referring to FIG. 12, metal seed layer 110 is deposited, for example, through Physical Vapor Deposition (PVD). The respective process is illustrated as process 304 in the process flow 202 as shown in FIG. 28. In accordance with some embodiments, metal seed layer 110 has a multi-layer structure, for example, including sub layer 106 and sub layer 108 on sub layer 106. In accordance with some example embodiments, sub layer 106 is formed of or comprises titanium, and sub layer 108 is formed of or comprises copper. In accordance with alternative embodiments, metal seed layer 110 is a single-layer formed of a homogeneous material, which may comprise copper. Accordingly, the interface between sub layers 106 and 108 is shown using a dashed line to indicate that metal seed layer 110 may or may not include sub layers.

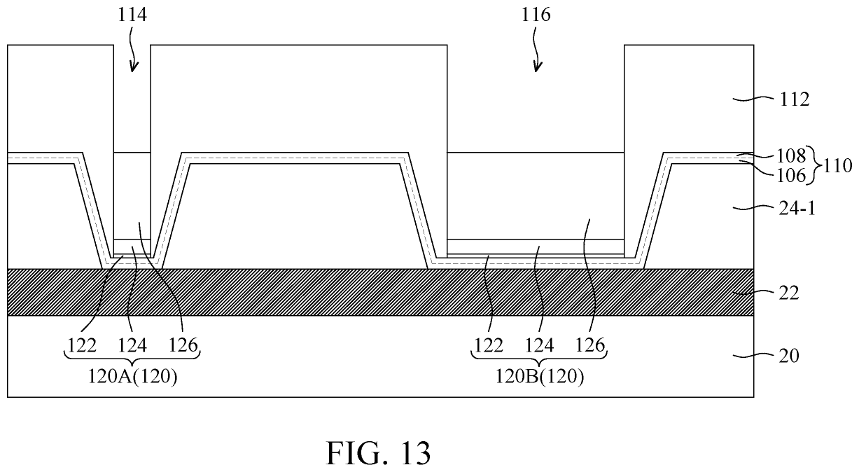

Plating mask 112 is formed over metal seed layer 110, and is patterned to form openings 114 and 116, respectively. The respective process is illustrated as process 306 in the process flow 202 as shown in FIG. 28. In accordance with some embodiments, plating mask 112 comprises a photoresist, which is patterned through light-exposure and development. Openings 114 and 116 are formed in plating mask 112, and extend into openings 102 and 104, respectively. Some portions of metal seed layer 110 at the bottoms of openings 102 and 104 are exposed to openings 114 and 116, respectively. The widths W3 of opening 102 and width W4 of opening 104 are smaller than the width W1 and W2, respectively. For example, ratios W3/W1 and W4/W2 may be in the range between about 0.6 and about 0.9. This allows the maximized widths of barrier layers 124 (FIG. 13), while leaving enough margin, so that openings 114 and 116 are limited inside the range of openings 102 and 104, respectively.

Referring to FIG. 13, a plurality of plating processes are preformed to form embedded vias 120A and 120B, which are collectively referred to embedded vias 120. The respective process is illustrated as process 308 in the process flow 202 as shown in FIG. 28. The plating may be performed using, for example, an electrochemical plating process(es), an electroless plating process(es), or the like. In accordance with some embodiments, the plating processes include a first plating process to plate metal layers 122, a second plating process to plate barrier layers 124, and a third plating process to plate metal layers 126.

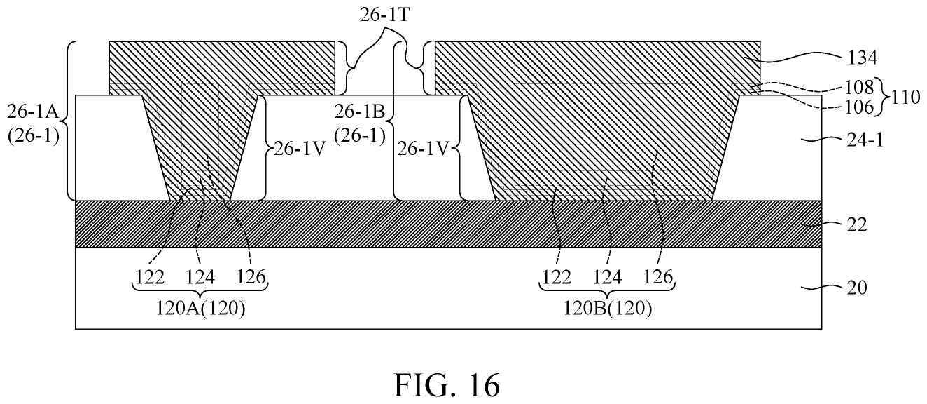

Barrier layers 124 are more resistant to diffusion and the subsequent formation of IMCs than metal layers 122. In accordance with some embodiments, metal layers 122 and 126 are formed of or comprise copper. Barrier layers 124 may be formed of or comprise nickel, cobalt, or the like, or the alloy thereof. The top surfaces of metal layers 126 may be higher than, coplanar with or lower than the top surface of dielectric layer 24-1, so that it is easier for the subsequently formed RDLs 26-1 (FIG. 16) to have planar top surfaces. In accordance with some embodiments, metal layers 122 are thin, so that the volume of the subsequent formation of IMCs is limited. Metal layers 122 also cannot be too thin. Otherwise, it cannot form an effective base to the formation f barrier layer 124 with high quality. For example, the thickness of metal layers 122 may be in the range between about 1 μm and about 5 μm. Barrier layers 124 cannot be too thin. Otherwise, they cannot act as an effective barrier. Barrier layers 124 also cannot be too thick. Otherwise, the resistance of the resulting embedded vias will be too high. For example, the thickness of barrier layers 124 may be in the range between about 1 μm and about 5 μm. The thickness of metal layers 126 may be equal to or greater than thicknesses the thicknesses of metal layers 122 and barrier layers 124, and may be in the range between about 1 μm and about 10 μm.

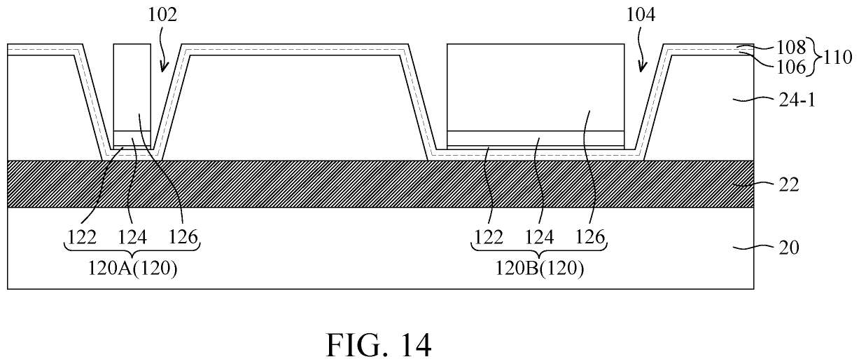

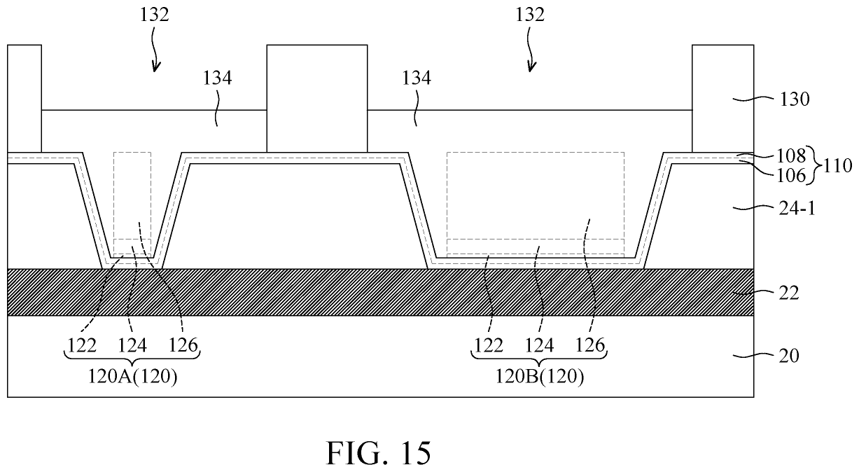

After the plating processes, plating mask 112 is removed. The respective process is illustrated as process 310 in the process flow 202 as shown in FIG. 28. The resulting structure is shown in FIG. 14. Next, referring to FIG. 15, plating mask 130 is formed, and is patterned to form openings 132, through which embedded vias 120A and 120B are exposed. The respective process is illustrated as process 312 in the process flow 202 as shown in FIG. 28. Plating mask 130 may also be formed of photoresist in accordance with some embodiments.

Next, a plating process is performed to plate metal layer 134. The respective process is illustrated as process 314 in the process flow 202 as shown in FIG. 28. The material of metal layer 134 may be the same as that of metal layers 122 and/or 126, and is different from the material of barrier layers 124. Accordingly, the interface between metal layer 134 and metal layers 122 and 126 are illustrated as being dashed to indicate that metal layer 134 may be, or may not be, distinguishable from metal layers 122 and 126. Also, in the embodiments in which metal seed layer 110 comprises copper, the copper in the metal seed layer 110 may not be distinguishable from metal layer 134. In accordance with some embodiments, metal layer 134 may be formed of or comprise copper, AlCu, or the like. The process is controlled, so that the top surfaces of metal layers 134 are planar. The formation of embedded vias 120 helps to form the metal layers 134 with planar top surfaces.

In a subsequent process, plating mask 130 is removed, and the underlying portions of metal seed layer 110 are exposed. The respective process is illustrated as process 316 in the process flow 202 as shown in FIG. 28. The exposed portions of metal seed layer 110 are then etched, with the resulting structure being shown in FIG. 16. The respective process is illustrated as process 318 in the process flow 202 as shown in FIG. 28. RDLs 26-1A and 26-1B are thus formed, and are collectively referred to as RDLs 26-1, which are also illustrated in FIG. 2 in accordance with some embodiments.

In accordance with some embodiments, as shown in FIG. 16, RDLs 26-1A and 26-1B include the trace portions 26-1T (also referred to as traces), which are higher than dielectric layer 24-1, and via portions (also referred to as vias) 26-1V in dielectric layer 24-1. RDLs 26-1A and 26-1B include embedded vias 120A and 120B therein, which may be fully inside vias 26-1V, or may extend slightly into trace portions 26-1T. The embedded vias 120A and 120B include barrier layers 124 embedded therein.

FIG. 26 illustrates a top view of RDL 26-1 or RDL 26-1B in accordance with some embodiments. The metal trace portion 26-1T may comprise or may form a metal pad, which may have a round top-view shape in accordance with some embodiments, while other top-view shapes such as rectangles, squares, hexagons, octagons, ovals, or the like, may also be adopted. Barrier layers 124 and embedded vias 120 have edges spaced apart from the edges of vias 26-1V. Accordingly Barrier layers 124 and embedded vias 120 are fully embedded in vias 26-1V when viewed from the top view, and are also fully embedded in the respective RDLs 26-1.

FIG. 3 illustrates the formation of additional dielectric layers 24-2 and 24-3, and the formation of additional RDLs 26-2 and electrical connectors 32. The respective process is illustrated as process 204 in the process flow 200 as shown in FIG. 27. Throughout the description, dielectric layers 24-1, 24-2, and 24-3 are individually and collectively referred to as dielectric layers 24, and RDLs 26-1 and 26-2 are individually and collectively referred to as RDLs 26. In accordance with some embodiments, dielectric layer 24-2 is first formed on RDLs 26-1. The bottom surface of dielectric layer 24-2 is in contact with the top surfaces of RDLs 26-1 and dielectric layer 24-1. Dielectric layer 24-2 may be formed of or comprise an organic dielectric material, which may be a polymer. For example, dielectric layer 24-2 may comprise a photo-sensitive material such as PBO, polyimide, BCB, or the like. Dielectric layer 24-2 is then patterned to form via openings (occupied by the via portions of RDLs 26-2) therein. Hence, some pad portions of RDLs 26-1 are exposed through the openings in dielectric layer 24-2.

In accordance with some embodiments, the formation of RDLs 26-2 may be similar to the formation of RDLs 26-1, which includes forming the metal seed layer, forming a first patterned plating mask, forming embedded vias, removing the first patterned plating mask, forming a second plating mask, plating a metal layer, removing the second plating mask, and etching the metal seed layer. RDLs 26-2 may have the same structure as RDLs 26-1, except that the embedded vias in RDLs 26-2 may be formed of a homogeneous material, and may be free from barrier layer therein. In accordance with alternative embodiments, in the formation of RDLs 26-2, the formation of embedded vias is skipped.

After the formation of a top dielectric layer such as dielectric layer 24-3, electrical connectors 32 may be formed. Electrical connectors 32 may be formed of or comprise micro-bumps, metal pads, metal pillars, Under-Bump-Metallurgies (UBMs), solder regions, and/or the like. The formation of electrical connectors 32 may include patterning the top dielectric layer to expose the underlying RDLs, forming a metal seed layer, forming a patterned plating mask, performing one or a plurality of plating processes to form metal pillars 32, removing the plating mask, and etching the metal seed layer. Electrical connectors 32 may also include copper, aluminum, cobalt, nickel, gold, silver, tungsten, alloys thereof, and/or multi-layers thereof. When electrical connectors 32 include solder regions, the solder regions may be plated using the same plating mask used for plating the underlying non-solder portions, followed by a reflow process to round the surfaces of the solder regions. The solder regions may include Sn and Ag, and may or may not include gold.

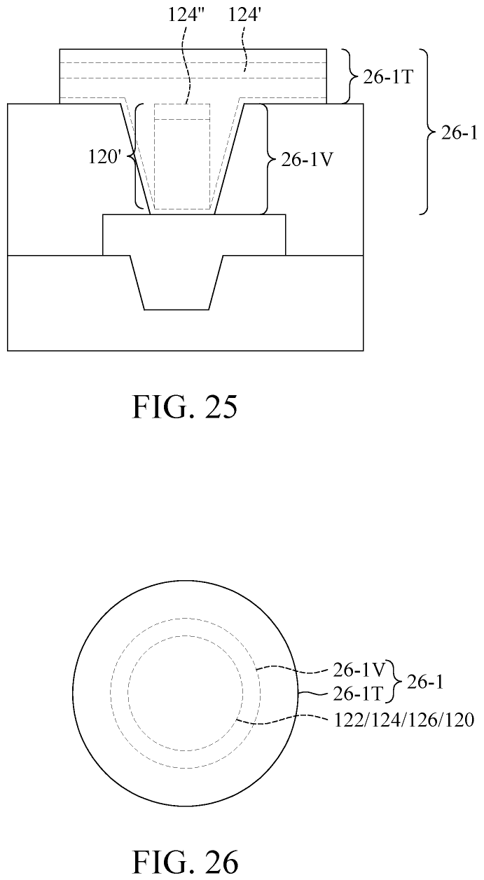

In accordance with some embodiments, electrical connectors 32 also include barrier layers therein, which may be formed of or comprise nickel, cobalt, or the like, or the alloy thereof. FIG. 25 schematically illustrates a magnified view of one of electrical connectors 32 as an example. In accordance with some embodiments, barrier layer 124′ is formed in the trace portion, and may extend to the edges of the trace portion of the electrical connector 32. In accordance with alternative embodiments, barrier layer 124″ is formed in the via portion of electrical connector 32. In accordance with these embodiments, barrier layer 124″ may be formed as a top layer of the respective embedded via 120′, while the underlying portion of embedded vias 120′ may be formed of a homogeneous material, which may be or may comprise copper.

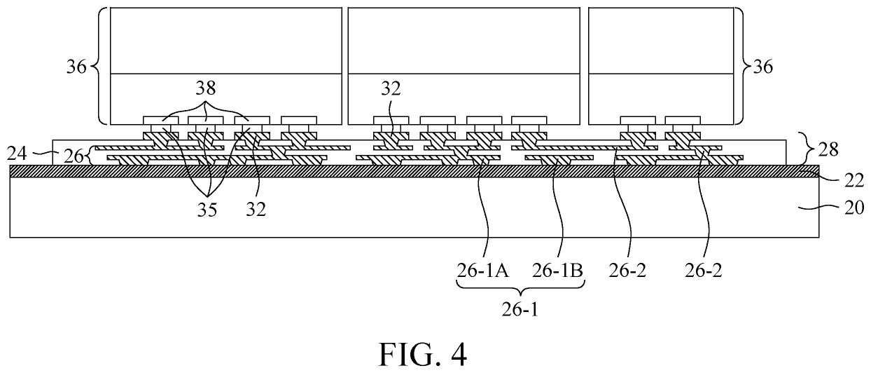

It is appreciated that although the top surface of barrier layer 124″ is illustrated as being coplanar with the top surface of via 26-1V, it may also be higher than (thus extending into the trace portion) or lower than the top surface of via 26-1V. Forming barrier layer 124′ or 124″ in a higher position of electrical connector 32 (or in embedded via 120′) may reduce the thickness of the portion of the metal over barrier layer 124′. This may result in reduced IMC formation with the overlying solder regions (such as solder regions 35 in FIG. 4), for example, in the subsequent high-temperature storage.

FIG. 4 illustrates the bonding of package components 36 to the redistribution structure 28. The respective process is illustrated as process 206 in the process flow 200 as shown in FIG. 27. Electrical connectors 38, which are the surface features of package components 36, may be bonded to electrical connectors 32 through solder regions 35 in accordance with some embodiments. Electrical connectors 38 may be UBMs, metal pillars, bond pads, or the like. In accordance with alternative embodiments, electrical connectors 38 are metal pillars, and are bonded to electrical connectors 32 through direct metal-to-metal bonding, with no solder regions therebetween.

In accordance with some embodiments, package components 36 include a plurality of groups of package components, with the groups being identical to each other. Each of the groups may be a single-component group or a multi-component group. For example, FIG. 3 illustrates an example in which each group includes three package components 36. In accordance with some embodiments, package components 36 include a logic die, which may be a Central Processing Unit (CPU) die, a Graphic Processing Unit (GPU) die, a mobile application die, a Micro Control Unit (MCU) die, an input-output (IO) die, a BaseBand (BB) die, an Application processor (AP) die, or the like. Package components 36 may also include memory dies such as Dynamic Random-Access Memory (DRAM) dies, Static Random-Access Memory (SRAM) dies, or the like. The memory dies may be discrete memory dies, or may be in the form of a die stack that includes a plurality of stacked memory dies. Package components 36 may also include System-on-Chip (SOC) dies. Package components 36 may be discrete device dies or packages.

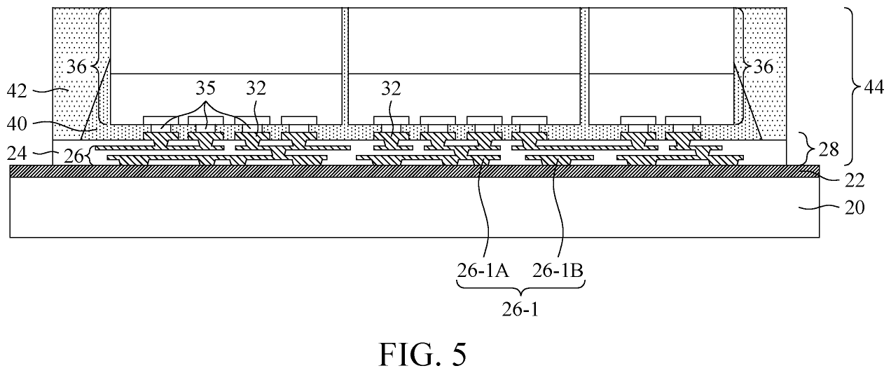

Referring to FIG. 5, underfill 40 is dispensed into the gaps between package components 36 and redistribution structure 28. The respective process is illustrated as process 208 in the process flow 200 as shown in FIG. 27. Underfill 40 may also be dispensed between neighboring package components 36 that are in the same group of package components. In accordance with some embodiments, underfill 40 includes a base material and filler particles mixed in the base material. The base material may be a resin, an epoxy, and/or a polymer. Some example base materials include epoxy-amine, epoxy anhydride, epoxy phenol, or the like, or combinations thereof. The filler particles may be formed of a dielectric material, and may include silica, alumina, boron nitride, or the like. The filler particles may have spherical shapes. Underfill 40 is dispensed in a flowable form, and is then cured. In accordance with alternative embodiments, underfill 40 is formed of a non-conductive film, which is placed on redistribution structure 28 first, and package components 36 are pressed against redistribution structure 28, so that the electrical connectors in package components 36 penetrate through the non-conductive film to contact electrical connectors 32.

Next, package components 36 are encapsulated in encapsulant 42. The respective process is illustrated as process 210 in the process flow 200 as shown in FIG. 27. Encapsulant 42 may be a molding compound, a molding underfill, an epoxy, and/or a resin. Encapsulant 42 may include a base material, and a filler in the base material. The base material may include a polymer material, which may be or may comprise a plastic, an epoxy resin (such as Epoxy Cresol Novolac (ECN), biphenyl epoxy resin, or a multifunctional liquid epoxy resin), polyimide, polyethylene terephthalate (PET), polyvinyl chloride (PVC), polymethylmethacrylate (PMMA), or the like. The filler may include titanium dioxide, carbon black, calcium carbonate, silica, fiber, clay, ceramic, inorganic particles, and or the like, and may be in the form of filler particles.

A planarization process such as a Chemical Mechanical Polish (CMP) process or a mechanical grinding process is then performed to polish encapsulant 42. Package components 36 may be exposed as a result of the planarization process. For example, when package components 36 comprise semiconductor substrates, the semiconductor substrates may be exposed. Throughout the description, the features over release film 22, which features include redistribution structure 28, package components 36, underfill 40, and encapsulant 42, are collectively referred to as reconstructed wafer 44.

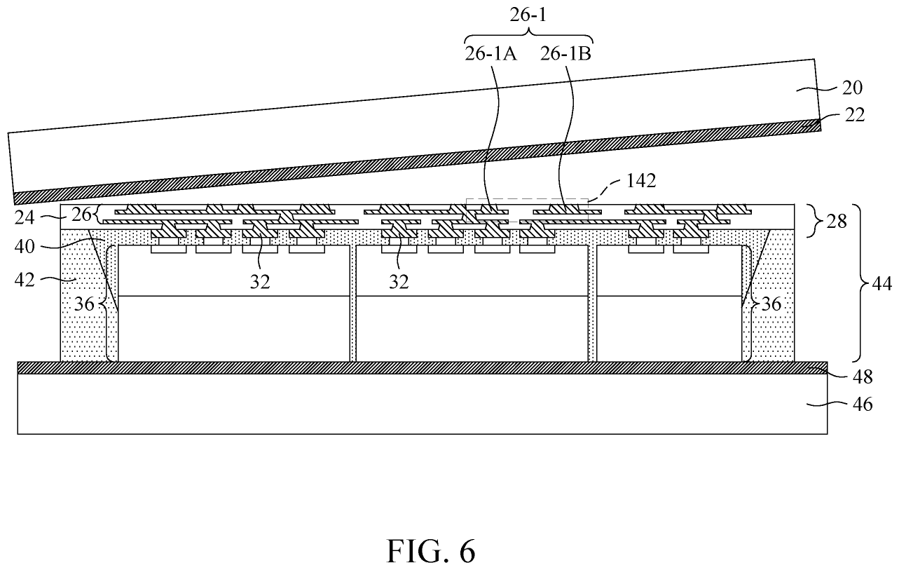

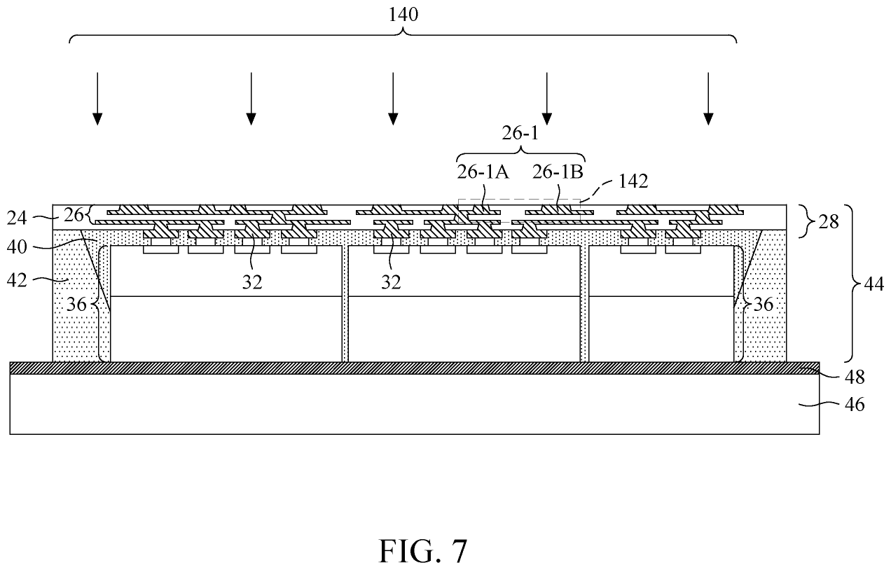

FIG. 6 illustrates a carrier switch process. The respective process is illustrated as process 212 in the process flow 200 as shown in FIG. 27. First, carrier 46 is adhered to an opposite side of the reconstructed wafer 44 than carrier 20. Release film 48, which may also comprise a thermal release film such as LTHC, is used to adhere carrier 46 to the reconstructed wafer 44. The reconstructed wafer 44 is then de-bonded from carrier 20, for example, by projecting UV light or a laser beam penetrating through carrier 20 and on release film 22. Release film 22 decomposes under the heat of the UV light or the laser beam. The reconstructed wafer 44 may then be de-bonded from carrier 20. The resulting reconstructed wafer 44 is illustrated in FIG. 7.

Further referring to FIG. 7, an etching/cleaning (etching and/or cleaning) process 140 is performed, which process cleans the residues left in the preceding processes. The respective process is illustrated as process 214 in the process flow 200 as shown in FIG. 27. When the metal seed layer 110 includes titanium as a part of the respective metal seed layer, the titanium is also removed, for example, in a dry etch process, so that the underlying copper, which may belong to the sub layer that comprises copper, or belong to the plated metal layer 134 (if the copper layer 108 is also etched due to its small thickness), is exposed.

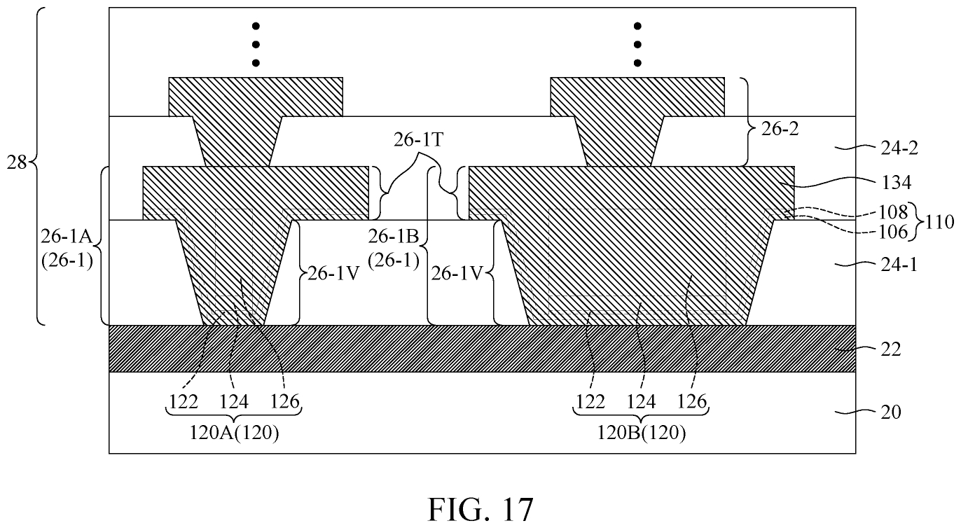

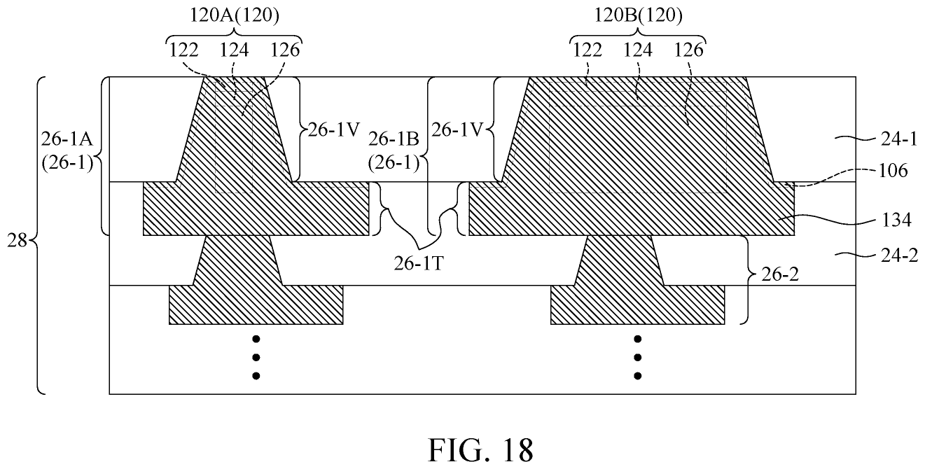

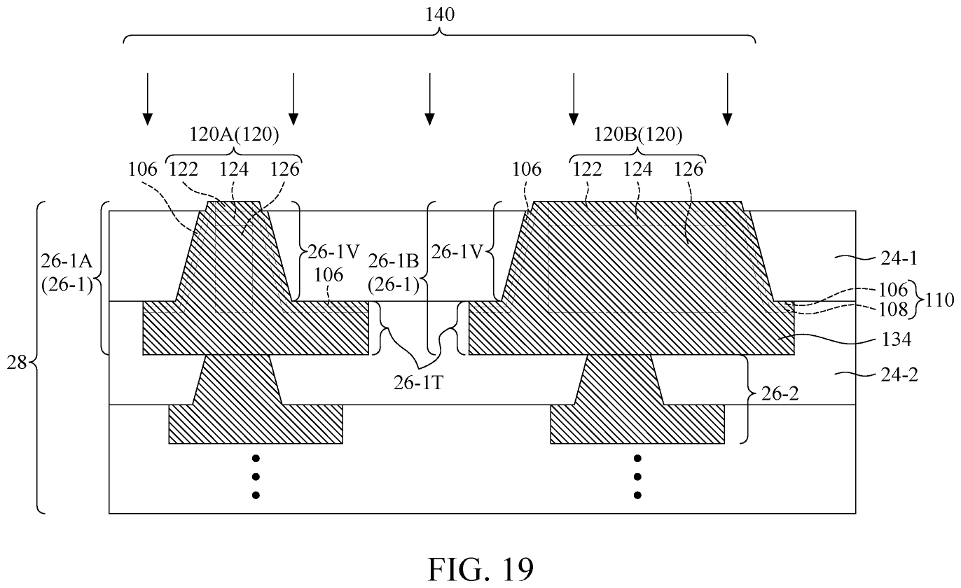

Magnified views of some processes shown in FIG. 3-7 are shown in FIGS. 17 through 20 in accordance with some embodiments. FIG. 17 (correspond to FIG. 3) illustrates the formation of more layers (such as dielectric layers 24-2 and 24-3, RDLs 26-2, and electrical connectors 32 in FIG. 3) to finish the formation of redistribution structure 28. FIG. 18 illustrates the structure before the etching/cleaning process 140 corresponding to FIG. 7. FIG. 19 illustrates the structure after the etching/cleaning process 140 corresponding to FIG. 7. The top portions of sub layer 106 (such as a titanium layer) is removed, while the portions of sub layer 108 in dielectric layer 24-1 may be removed (as illustrated in FIG. 19) or may remain. The illustrated top surface of dielectric layer 24-1 may also be recessed due to the etching/cleaning process 140. In accordance with some embodiments, the top surfaces of barrier layers 124 may be higher than, coplanar with, or lower than, the top surface of dielectric layer 24-1. Barrier layers 124 may also have the upper portions, or entireties, higher than the top surface of dielectric layer 24-1.

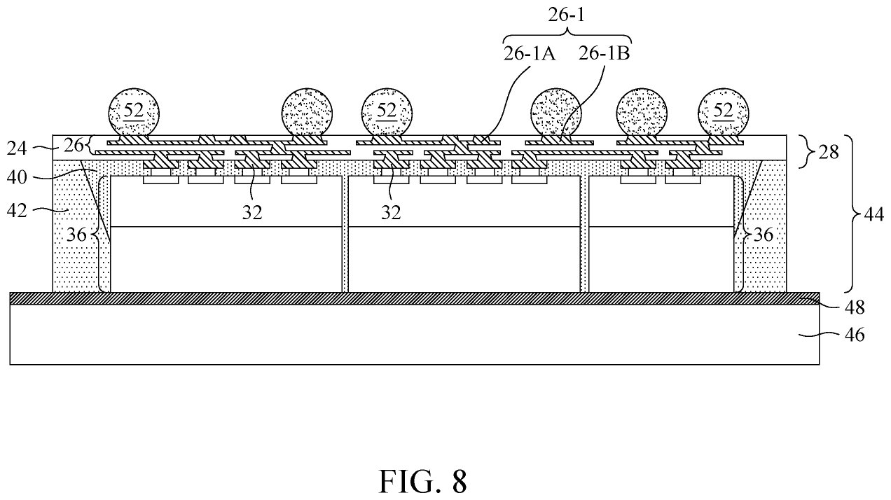

FIG. 8 illustrates the formation of solder regions 52. The respective process is illustrated as process 216 in the process flow 200 as shown in FIG. 27. In accordance with some embodiments, the formation process includes placing solder balls on RDLs 26-1, and performing a reflow process.

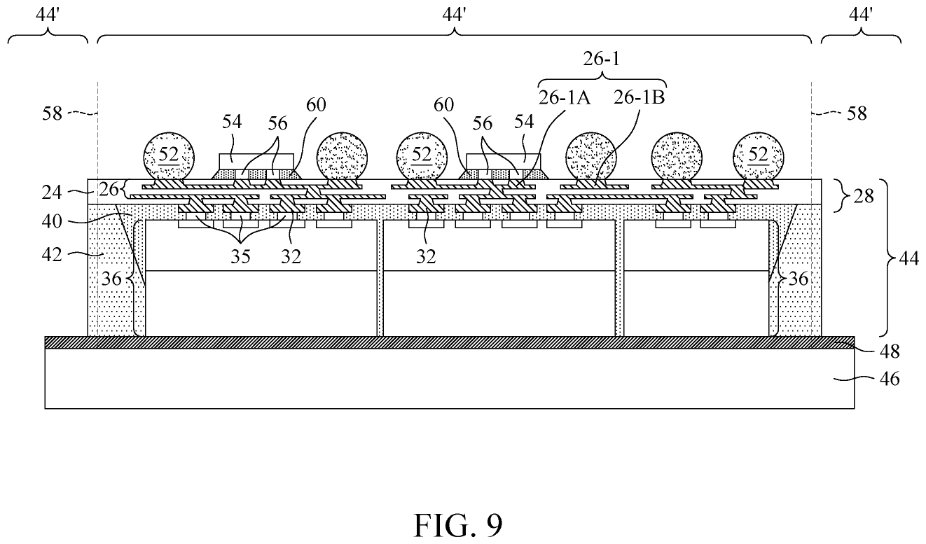

FIG. 9 illustrates the bonding of dies 54 to redistribution structure 28 through metal bump 56. The respective process is illustrated as process 218 in the process flow 200 as shown in FIG. 27. Next, underfill 60 is dispensed into the gaps between dies 54 and redistribution structure 28. Dies 54 may include Intelligent Power Devices (referred to as IPDs), which may include high-performance semiconductor power switches with built-in protection circuits capable of absorbing energy such as inductive loads. In accordance with alternative embodiments, dies 54 may include an independent passive device (also referred to as an IPD) such capacitor(s), a resistor(s), a transmitter(s) therein. Dies 54 may also be bridge dies. In the subsequent discussion, dies 54 are referred to as IPDs 54, while they may also be of another type such as bridge dies.

Referring again to FIG. 9, in a subsequent process, reconstructed wafer 44 is de-bonded from carrier 46, for example, by projecting UV light or a laser beam, which penetrates through carrier 46 to reach release film 48. Release film 48 decomposes under the heat of the UV light or the laser beam. The reconstructed wafer 44 is thus separated from carrier 46. Reconstructed wafer 44 may be placed on a dicing tape (not shown), which is attached and fixed on a frame (not shown). The reconstructed wafer 44 is then sawed in a singulation process along scribe lines 58, so that packages 44′, which are identical to each other, are separated from each other. The respective process is illustrated as process 220 in the process flow 200 as shown in FIG. 27.

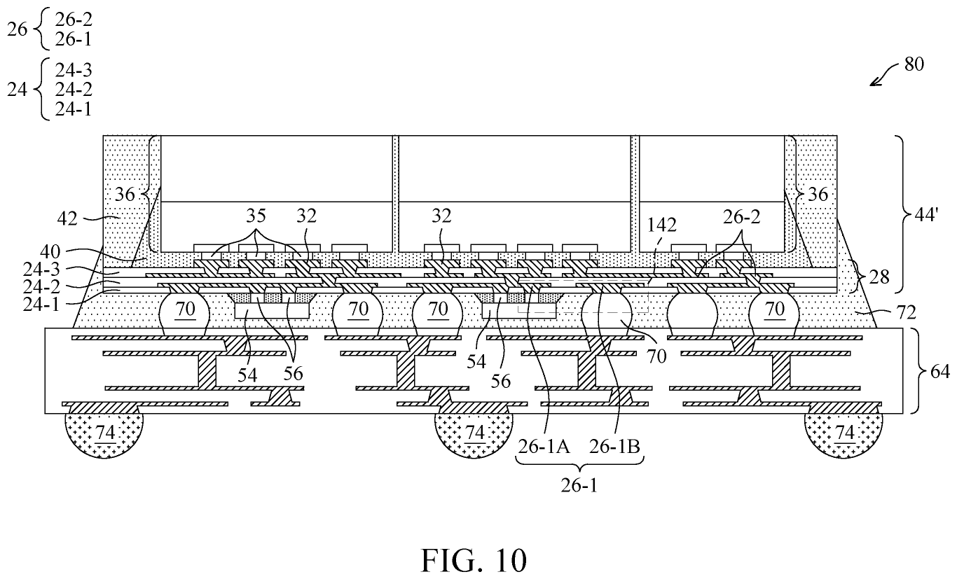

FIG. 10 illustrates the alignment of package 44′ to package component 64. In accordance with some embodiments, package component 64 may be or may comprise a package substrate (cored or core-less), an interposer, a package including device dies therein, a device die, a printed circuit board, or the like.

Next, a reflow process is performed, so that package 44′ is bonded to package component 64. The respective process is illustrated as process 222 in the process flow 200 as shown in FIG. 27. Solder regions 70 are formed to bond redistribution structure 28 to package component 64.

Further referring to FIG. 10, underfill 72 is dispensed into the gap between package 44′ and package component 64. Accordingly, underfill 72 also encapsulates IPD 54 therein. The respective process is illustrated as process 224 in the process flow 200 as shown in FIG. 27. Underfill 72 may be in contact with and encapsulate solder regions 70.

FIG. 10 further illustrates the formation of electrical connectors 74, which are electrically connected to package 44′ through package component 64. Package 80 is thus formed. In accordance with some embodiments, the formation of electrical connectors 74 includes etching a bottom dielectric layer in package component 64 to reveal the metal pads in in package component 64, and forming electrical connectors 74. In accordance with some embodiments, electrical connectors 74 include solder regions, which may be formed by placing solder balls on the metal pads, and then performing a reflow process.

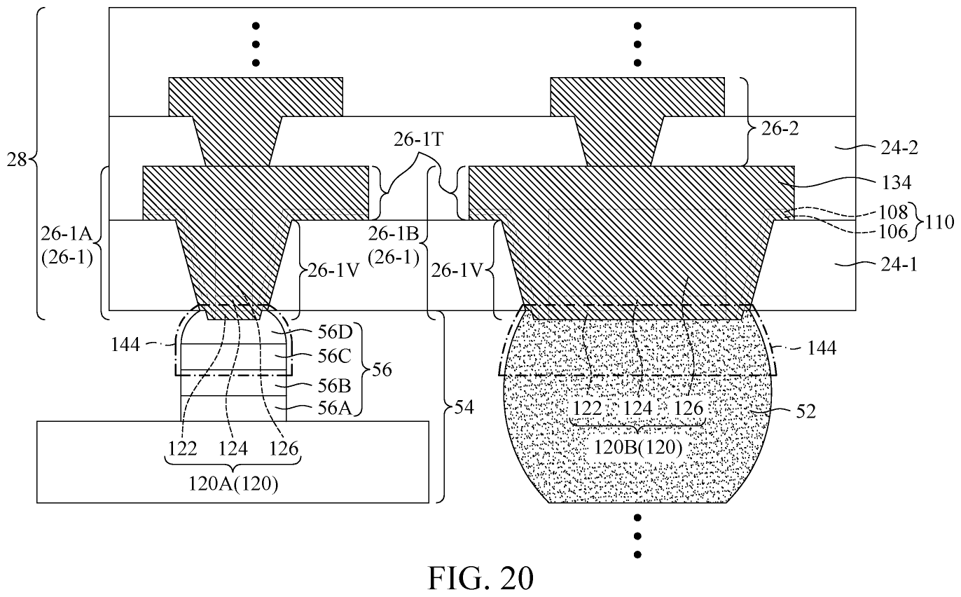

FIG. 20 illustrates a magnified view of the bonding structure shown in FIG. 10, wherein the illustrated features may be found in region 142 in FIG. 10. Via 26-1V (also referred to as a bond pad) is bonded to IPD 54 through metal bump 56, which may be a part of IPD 54 in accordance with some embodiments. In accordance with some embodiments, metal bump 56 includes sub layer 56A, barrier layer 56B, sub layer 56C, and solder region 56D. Sub layers 56A and 56C may be formed of or comprise copper. Barrier layer 56B may be formed of or comprise nickel, cobalt, or the like. Solder region 56D may comprise Sn. For example, solder region 56D may be a lead-free solder formed of AgSn in accordance with some embodiments.

It is appreciated that sub layer 56D, which may be formed of solder, tends to form IMC with the copper in via 26-1V. For example, the copper in via 26-1V may form IMC CuSn with the Sn in solder region 56D. The formation of the IMC may occur during the subsequent thermal processes and the high-temperature storage of the resulting package 80. The IMC may be formed in regions 144. In accordance with some embodiments, all features in regions 144 are compounded to form the IMCs. It is appreciated that the formed IMCs may have a volume substantially equal to or smaller than the total volume of the consumed solder region 56D and the consumed copper in sub layer 56D. Accordingly, voids may be formed due to the formation of the IMCs. Furthermore, the voids are related to the amount of IMCs, and the more IMC is formed (and the more solder and copper are consumed), the voids are more likely to form, and the size of the voids are more likely to be significant.

In accordance with some embodiments, barrier layers 124 are formed, and the metal layers 122 are formed as thin layers. Barrier layers 124 are formed of materials that are not prone to diffusion, and are not prone to forming IMCs. Accordingly, barrier layers 124 also act as the barrier layers for the IMCs to grow. Furthermore, when some parts of the barrier layers 124 also form the IMCs with the metal layer 122 and solder regions 56D, the volume of the resulting IMCs will be closer to the total volume of the consumed materials, thus even if the IMCs are formed, the voids are less likely to occur.

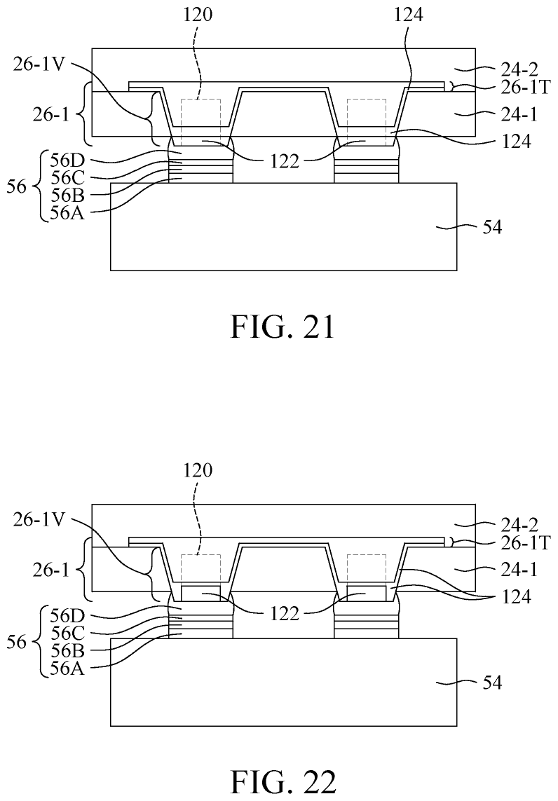

FIGS. 21 through 25 illustrate some bond structures in accordance with alternative embodiments of the present disclosure. Referring to FIG. 21, barrier layer 124 may be formed as a conformal layer extending to the edges of via 26-1, and may be in contact with dielectric layer 24-1. Barrier layer 124 may also extend into metal trace 26-1T. Metal layers 122, which may be formed of copper, are underlying the respective conformal barrier layers 124. The sidewalls of metal layers 122 may be in contact with solder regions 56D to form interfaces. The formation process of the structure show in FIG. 21 may include a bottom-up formation process for forming metal layers 122, a conformal deposition process to form barrier layers 124, forming metal layers 126, and plating metal layers 134.

FIG. 22 illustrates a bond structure in accordance with alternative embodiments. These embodiments are similar to the embodiments as shown in FIG. 21, except that barrier layer 124 extends to the sidewalls of dielectric layer 24-1, and extends to contact solder region 56D. Accordingly, barrier layers 124 also reduce the formation of the IMCs grown from the sidewalls of metal layers 122. The formation process of the structure shown in FIG. 22 may include forming metal layers 122, performing a conformal deposition process to form barrier layers 124, forming metal layers 126, and plating metal layers 134.

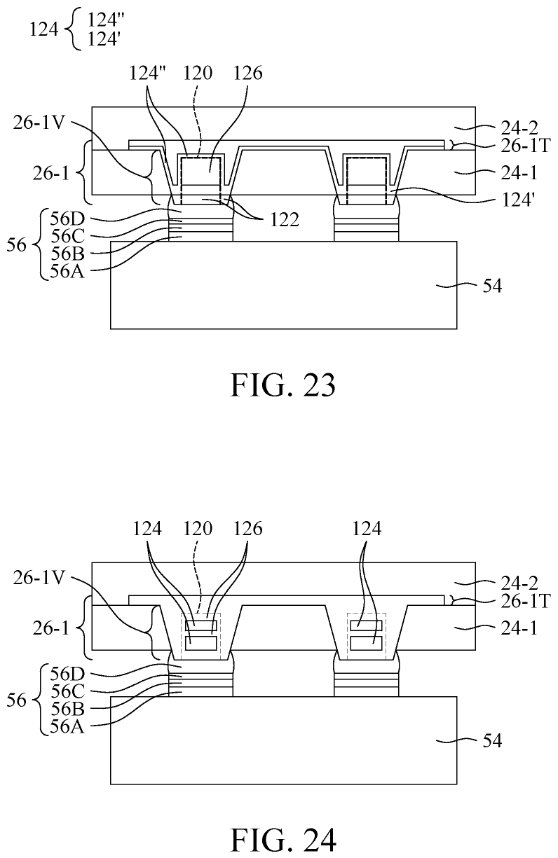

FIG. 23 illustrates the bond structure in accordance with alternative embodiments. These embodiments are similar to the embodiments as shown in FIG. 21, except that barrier layers 124 (including 124′ and 124″) extend to the sidewalls of dielectric layer 24-1 and the sidewalls and the top surface of metal layer 126, which may be formed of copper. In accordance with these embodiments, barriers layer 124 may be formed in two processes, one before the formation of metal layer 122 to form barrier layers 124′, and one after the formation of metal layer 126 to form barrier layers 124′.

FIG. 24 illustrates the bond structure in accordance with alternative embodiments. These embodiments are similar to the embodiments as shown in FIG. 21, except that there are a plurality of barrier layers 124 and a plurality of copper layers 126. The formation process may be realized from the preceding embodiments.

The embodiments of the present disclosure have some advantageous features. By forming embedded vias having barrier layers therein, the formation of IMCs is reduced. Accordingly, the possibility of the formation of voids due to the formation of the IMCs is reduced.

In accordance with some embodiments of the present disclosure, a method comprises forming a redistribution line over a carrier, wherein the forming the redistribution line comprises forming a via and a metal trace over and joined to the via, and wherein the forming the redistribution line comprises depositing a first metal layer; depositing a barrier layer over the first metal layer; and depositing a second metal layer over the barrier layer; de-bonding the redistribution line from the carrier; and bonding a package component to the redistribution line, wherein a metal bump bonds the package component to the via. In an embodiment, the forming the redistribution line comprises forming an embedded via comprising the first metal layer, the barrier layer, and the second metal layer; and depositing an additional metal layer on the embedded via.

In an embodiment, the method further comprises forming a dielectric layer; and forming an opening in the dielectric layer, wherein the embedded via is formed in the opening. In an embodiment, the barrier layer is fully embedded in the via. In an embodiment, the method further comprises, after the de-bonding, performing an etching process on the via to remove a first part of a metal seed layer, wherein a second part of the metal seed layer forms a portion of the via. In an embodiment, the metal bump comprises a solder layer contacting the via. In an embodiment, the depositing the first metal layer, the barrier layer, and the second metal layer comprises depositing a first copper layer, a nickel layer, and a second copper layer, respectively.

In an embodiment, the first metal layer has a thickness smaller than about 5 μm. In an embodiment, the forming the redistribution line further comprises depositing an additional barrier layer over the second metal layer, wherein the barrier layer and the additional barrier layer have corresponding edges vertically aligned to each other. In an embodiment, the method further comprises forming an additional redistribution line over and electrically connecting to the redistribution line.

In accordance with some embodiments of the present disclosure, a structure comprises a redistribution structure comprising a redistribution line, wherein the redistribution line comprises a via comprising a first metal layer; a barrier layer over the first metal layer; and a second metal layer over the barrier layer; and a metal trace over and joined to the via; and a package component comprising a metal bump bonding to the via, wherein the metal bump comprises a solder region physically joined to the via. In an embodiment, the barrier layer is fully enclosed in the via. In an embodiment, the structure further comprises an additional barrier layer over the second metal layer, wherein edges of the additional barrier layer are vertically aligned to respective edges of the barrier layer.

In an embodiment, the first metal layer and the second metal layer comprise a first metallic material, and the barrier layer comprises a second metallic material different from the first metallic material. In an embodiment, the first metal layer has a first thickness smaller than a second thickness of the second metal layer. In an embodiment, the solder region contacts a bottom surface and sidewalls of a bottom portion of the via. In an embodiment, the structure further comprises a dielectric layer, wherein at least an upper portion of the via is in the dielectric layer, and wherein the barrier layer is spaced apart from sidewalls of the dielectric layer, with the sidewalls contacting the via.

In accordance with some embodiments of the present disclosure, a structure includes a first dielectric layer; a second dielectric layer over and contacting the first dielectric layer; a via comprising at least an upper portion in the first dielectric layer, wherein the via comprises a copper region; and a barrier layer embedded in the copper region; a metal line in the second dielectric layer, wherein the metal line is joined to the via; and a metal bump underlying and contacting the via, wherein the solder region is spaced apart from the barrier layer. In an embodiment, a portion of the copper region encircles the barrier layer, and spaces the barrier layer apart from the barrier layer. In an embodiment, the barrier layer is a planar layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a redistribution line over a carrier, wherein the forming the redistribution line comprises forming a via and a metal trace over and joined to the via, and wherein the forming the redistribution line comprises:
depositing a first metal layer;
depositing a barrier layer over the first metal layer; and
depositing a second metal layer over the barrier layer;
de-bonding the redistribution line from the carrier; and
bonding a package component to the redistribution line, wherein a metal bump bonds the package component to the via.

2. The method of claim 1, wherein the forming the redistribution line comprises:
forming an embedded via comprising the first metal layer, the barrier layer, and the second metal layer; and
depositing an additional metal layer on the embedded via.

3. The method of claim 2 further comprising:
forming a dielectric layer; and
forming an opening in the dielectric layer, wherein the embedded via is formed in the opening.

4. The method of claim 1, wherein the barrier layer is fully embedded in the via.

5. The method of claim 1 further comprising, after the de-bonding, performing an etching process on the via to remove a first part of a metal seed layer, wherein a second part of the metal seed layer forms a portion of the via.

6. The method of claim 1, wherein the metal bump comprises a solder layer contacting the via.

7. The method of claim 1, wherein the depositing the first metal layer, the barrier layer, and the second metal layer comprises depositing a first copper layer, a nickel layer, and a second copper layer, respectively.

8. The method of claim 1, wherein the first metal layer has a thickness smaller than about 5 μm.

9. The method of claim 1, wherein the forming the redistribution line further comprises depositing an additional barrier layer over the second metal layer, wherein the barrier layer and the additional barrier layer have corresponding edges vertically aligned to each other.

10. The method of claim 1 further comprising forming an additional redistribution line over and electrically connecting to the redistribution line.

11. A structure comprising:
a redistribution structure comprising a redistribution line, wherein the redistribution line comprises:
a via comprising:
a first metal layer;
a barrier layer over the first metal layer; and
a second metal layer over the barrier layer; and
a metal trace over and joined to the via; and
a package component comprising a metal bump bonding to the via, wherein the metal bump comprises a solder region physically joined to the via.

12. The structure of claim 11, wherein the barrier layer is fully enclosed in the via.

13. The structure of claim 11 further comprising an additional barrier layer over the second metal layer, wherein edges of the additional barrier layer are vertically aligned to respective edges of the barrier layer.

14. The structure of claim 11, wherein the first metal layer and the second metal layer comprise a first metallic material, and the barrier layer comprises a second metallic material different from the first metallic material.

15. The structure of claim 11, wherein the first metal layer has a first thickness smaller than a second thickness of the second metal layer.

16. The structure of claim 11, wherein the solder region contacts a bottom surface and sidewalls of a bottom portion of the via.

17. The structure of claim 11 further comprising a dielectric layer, wherein at least an upper portion of the via is in the dielectric layer, and wherein the barrier layer is spaced apart from sidewalls of the dielectric layer, with the sidewalls contacting the via.

18. A structure comprising:
a first dielectric layer;
a second dielectric layer over and contacting the first dielectric layer;
a via comprising at least an upper portion in the first dielectric layer, wherein the via comprises:
a copper region; and
a barrier layer embedded in the copper region;
a metal line in the second dielectric layer, wherein the metal line is joined to the via; and
a metal bump underlying and contacting the via, wherein the metal bump is spaced apart from the barrier layer.

19. The structure of claim 18, wherein a portion of the copper region encircles the barrier layer, and spaces the barrier layer apart from the barrier layer.

20. The structure of claim 18, wherein the barrier layer is a planar layer.
